(19) United States
(12) Patent Application Publication
(10) Pub. No.: US 2024/0242876 A1
(43) Pub. Date: Jul. 18, 2024

(54) CORELESS PLANAR COIL AND POWER TRANSFORMER

(71) Applicant: ABB SCHWEIZ AG, Baden (CH)

(72) Inventors: Huan Shi, Hangzhou, Zhejiang (CN); Yongfei Qu, Hangzhou, Zhejiang (CN); Wei Liu, Hangzhou, Zhejiang (CN); Jie Yuan

(21) Appl. No.: 18/561,723

(22) PCT Filed: Jul. 2, 2021
(86) PCT No.: PCT/CN2021/104388

§ 371 Date: Nov. 16, 2023

(51) Int. Cl. H01F 27/28; H05K 1/16; H05K 1/18

(52) U.S. Cl. CPC H01F 27/2847; H05K 1/165; H05K 1/188; H01F 2027/2819

(57) ABSTRACT

A coreless planar coil and a power transformer. The coreless planar coil includes a coil body arranged in a plane and configured to produce an alternating magnetic field for delivering signal or power; and a first metal ring arranged around the coil body in the plane and configured to produce a first magnetic field having a direction opposite to the alternating magnetic field produced by the coil body.

### FIELD

Embodiments of the present disclosure generally relate to the field of power transformers, and more particularly, to a coreless planar coil and a power transformer.

### BACKGROUND

A coreless planar coil is typically used in small-scale equipment with a low-power isolation power supply to deliver signal or power. The low-power isolation power supply includes a small isolated power supply, a DCS equipment power supply, and the like. However, a distribution range of a magnetic field generated by the coreless planar coil is usually very large, especially at the edge of the coreless planar coil. As a result, the magnetic field outside the coreless planar coil will disturb other nearby electronic systems, resulting in low efficiency and high crosstalk of the coreless planar coil. Thus, there is a need to reduce the distribution range of the magnetic field generated by the coreless planar coil so as to reduce the crosstalk and improve the efficiency of the coreless planar coil.

### SUMMARY

In view of the foregoing problems, various example embodiments of the present disclosure provide a coreless planar coil and a power transformer comprising the same to reduce the crosstalk of power transformer and improve the efficiency of the power transformer.

In a first aspect of the present disclosure, example embodiments of the present disclosure provide a coreless planar coil. The coreless planar coil comprises a coil body arranged in a plane and configured to produce an alternating magnetic field for delivering signal or power; and a first metal ring arranged around the coil body in the plane and configured to produce a first magnetic field having a direction opposite to the alternating magnetic field produced by the coil body. With these embodiments, the magnetic flux outside the coreless planar coil will be largely reduced and the magnetic flux inside the coreless planar coil will be maintained, thereby reducing the crosstalk and improving the efficiency of the coreless planar coil.

In some embodiments, the coreless planar coil is arranged on a PCB. With these embodiments, the coreless planar coil can be manufactured at a low cost.

In some embodiments, the coreless planar coil further comprises a second metal ring arranged inside the coil body in the plane and configured to produce a second magnetic field having a direction opposite to the alternating magnetic field produced by the coil body. With these embodiments, the magnetic field generated by the coil body is more concentrated between the first metal ring and the second metal ring.

In some embodiments, the first metal ring and the second metal ring are made of copper. With these embodiments, the magnetic flux outside the coreless planar coil can be reliably reduced by the first metal ring and the second metal ring at a low cost.

In some embodiments, the first metal ring and the second metal ring are made of copper foils on a PCB. With these embodiments, the cost of the coreless planar coil with the metal rings is substantially not increased compared to those without the metal rings.

In a second aspect of the present disclosure, example embodiments of the present disclosure provide a coreless power transformer. The coreless power transformer comprises a primary winding configured to transmit power received from a power supply; and a secondary winding configured to receive the power from the primary winding and provide the received power to a load, wherein at least one of the primary winding and the secondary winding comprises the coreless planar coil according to the first aspect of the present disclosure. Since the coreless power transformer comprises the coreless planar coil according to the first aspect of the present disclosure, the coreless power transformer may provide the same advantages.

In some embodiments, the primary winding and the secondary winding are arranged on different PCBs.

It is to be understood that the Summary section is not intended to identify key or essential features of embodiments of the present disclosure, nor is it intended to be used to limit the scope of the present disclosure. Other features of the present disclosure will become easily comprehensible through the following description.

### DESCRIPTION OF DRAWINGS

Through the following detailed descriptions with reference to the accompanying drawings, the above and other objectives, features and advantages of the example embodiments disclosed herein will become more comprehensible. In the drawings, several example embodiments disclosed herein will be illustrated in examples and in a non-limiting manner, wherein:

FIG. 1 is a schematic view illustrating a working scenario of a conventional coreless planar coil;

FIG. 2 is a schematic view illustrating a coreless planar coil in accordance with an embodiment of the present disclosure;

FIG. 3 is a schematic view illustrating a working scenario of a coreless planar coil in accordance with an embodiment of the present disclosure; and

FIG. 4 is a schematic view illustrating a power transformer in accordance with an embodiment of the present disclosure.

Throughout the drawings, the same or similar reference symbols are used to indicate the same or similar elements.

### DETAILED DESCRIPTION OF EMBODIMENTS

Principles of the present disclosure will now be described with reference to several example embodiments shown in the drawings. Though example embodiments of the present disclosure are illustrated in the drawings, it is to be understood that the embodiments are described only to facilitate those skilled in the art to better understand and thereby implement the present disclosure, rather than to limit the scope of the disclosure in any manner.

The term “comprises” or “includes” and its variants are to be read as open terms that mean “includes, but is not limited to.” The term “or” is to be read as “and/or” unless the context clearly indicates otherwise. The term “based on” is to be read as “based at least in part on.” The term “being operable to” is to mean a function, an action, a motion or a state that can be achieved by an operation induced by a user or an external mechanism. The term “one embodiment” and “an embodiment” are to be read as “at least one embodiment.” The term “another embodiment” is to be read as “at least one other embodiment.” The terms “first,” “second,” and the like may refer to different or same objects. Other definitions, explicit and implicit, may be included below. A definition of a term is consistent throughout the description unless the context clearly indicates otherwise.

According to embodiments of the present disclosure, a metal ring is arranged around a coil body so as to limit the magnetic field outside the coreless planar coil. The above idea may be implemented in various manners, as will be described in detail in the following paragraphs.

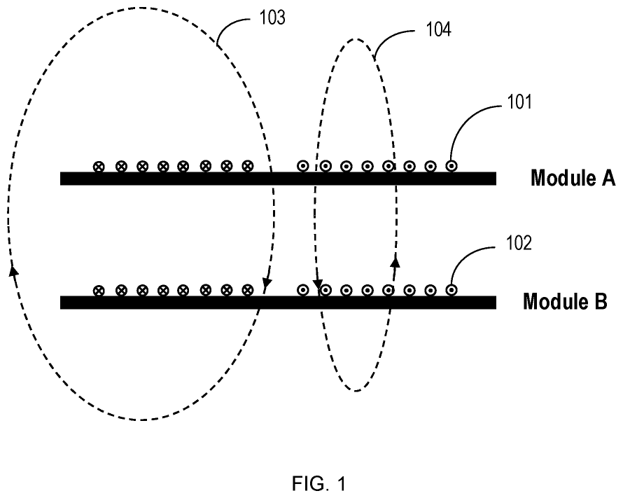

First, operational principles and problems of a conventional coreless planar coil will be described in detail with reference to FIG. 1. FIG. 1 is a schematic view illustrating a working scenario of the conventional coreless planar coil. As shown in FIG. 1, a first coreless planar coil 101 formed on a module A generates a magnetic field, and a second coreless planar coil 102 formed on a module B receives the magnetic field. Energy or signal may be delivered through the magnetic field.

As shown in FIG. 1, generally, there are two kinds of magnetic lines of force generated by the first coreless planar coil 101 formed on the module A. One kind of magnetic line of force 104 travels inside the boundary of the module A. The other kind of magnetic line of force 103 travels outside the boundary of the module A. Because the first coreless planar coil 101 has no core, the magnetic line of force will not be limited by any core. As a result, the distribution range in which the magnetic lines of force 103 and 104 travel is very large, especially the magnetic line of force 103. In this case, a crosstalk may be generated between the first coreless planar coil 101 and other nearby electronic systems.

Thus, there is a need to reduce the distribution range of the magnetic field generated by the coreless planar coil so as to reduce the crosstalk.

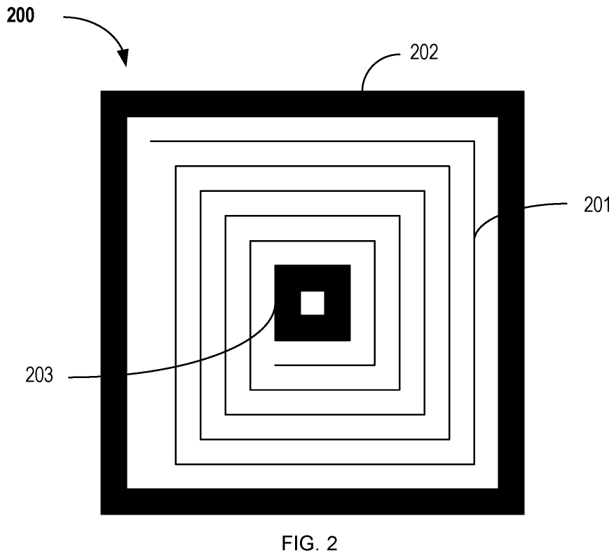

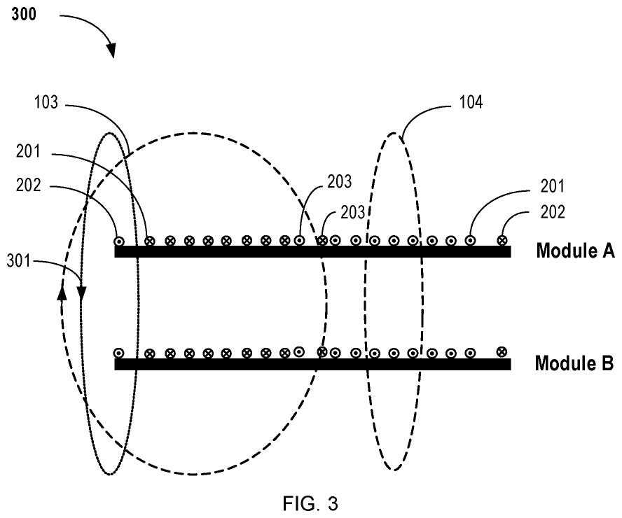

Hereinafter, the principles of an energy limiting circuit in accordance with embodiments of the present disclosure will be described in detail with reference to FIGS. 2-3. FIG. 2 is a schematic view illustrating a coreless planar coil in accordance with an embodiment of the present disclosure, and FIG. 3 is a schematic view illustrating a working scenario of a coreless planar coil in accordance with an embodiment of the present disclosure.

As shown in FIG. 2, the coreless planar coil 200 generally includes a coil body 201 and a first metal ring 202. The coil body 201 is arranged in a plane and is used to receive signal or power from a signal source or a power source, and generate an alternating magnetic field to deliver the signal or power. The first metal ring 202 is arranged around the coil body 201 in the plane, and is used to produce a first magnetic field having a direction opposite to the alternating magnetic field produced by the coil body 201.

As shown in FIG. 3, the coil body 201 generates an alternating magnetic field during operation. The alternating magnetic field comprises a magnetic line of force 103 travelling outside the first metal ring 202 and a magnetic line of force 104 travelling inside the first metal ring 202. According to the law of electromagnetic induction, the first metal ring 202 will be inducted by the magnetic line of force 103, and will produce a magnetic field. The magnetic field comprises a magnetic line of force 301 having a direction opposite to the magnetic line of force 103 outside the first metal ring 202, so as to suppress the change of the alternating magnetic field. Meanwhile, the magnetic field 301 produced by the first metal ring 202 will not react to the magnetic line of force 104 inside the first metal ring. As a result, the alternating magnetic field around the first metal ring 202 is suppressed and the alternating magnetic field inside the first metal ring 202 is maintained.

By reducing the distribution of magnetic field outside the first metal ring 202, the magnetic field generated by the coil body 201 is concentrated inside the first metal ring 202, and the amplitude of the magnetic field is decreased. As a result, the influence of the alternating magnetic field on the nearby electronic systems is reduced, and the influence of the alternating magnetic field on the electronic systems parallel to the coreless planar coil 200 is also reduced, and thus the reliability of the systems is improved.

In some embodiments, as shown in FIG. 2, the coreless planar coil 200 further comprises a second metal ring 203 arranged inside the coil body 201 in the plane. The second metal ring 203 is used to produce a second magnetic field having a direction opposite to the alternating magnetic field produced by the coil body 201. With such an arrangement, the magnetic field generated by the coil body 201 is more concentrated between the first metal ring 202 and the second metal ring 203.

In some embodiments, the coreless planar coil 200 is arranged on a PCB. In other embodiments, the coreless planar coil 200 can be arranged on other components. The scope of the present disclosure is not intended to be limited in this respect.

In some embodiments, as shown in FIG. 2, the first metal ring 202 and the second metal ring 203 may be of a rectangular shape. In other embodiments, the first metal ring 202 and the second metal ring 203 may be of other shapes, such as a circular shape or a polygonal shape. The scope of the present disclosure is not intended to be limited in this respect.

In some embodiments, the first metal ring 202 and the second metal ring 203 are made of copper. In this way, the magnetic flux outside the coreless planar coil can be reliably reduced by the first metal ring 202 and the second metal ring 203 at a low cost. In other embodiments, the first metal ring 202 and the second metal ring 203 can be made of other metals, for example, aluminum. The scope of the present disclosure is not intended to be limited in this respect.

In some embodiments, the first metal ring 202 and the second metal ring 203 are made of copper foils on a PCB. Compared to those without the metal rings, the cost of the coreless planar coil with these metal rings is substantially not increased.

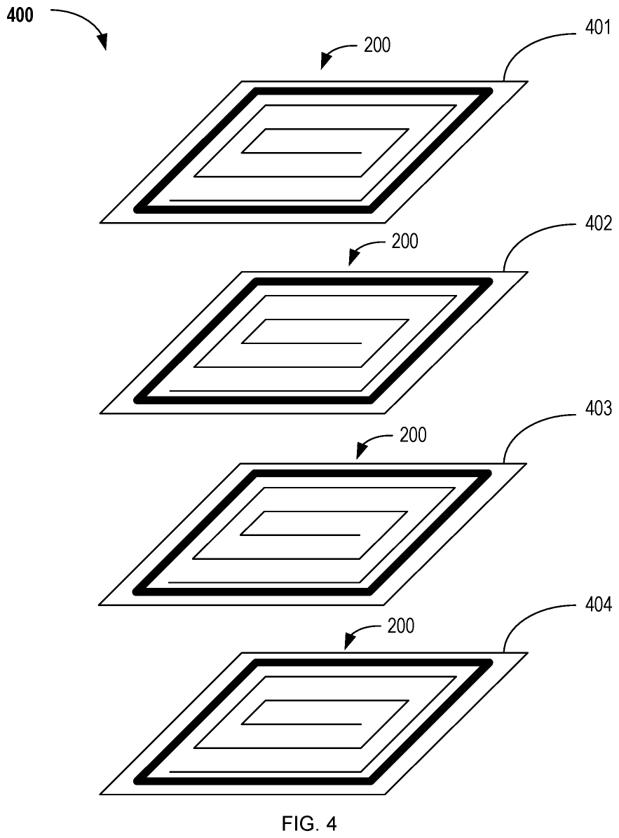

Hereinafter, the principles of a power transformer will be described in detail with reference to FIG. 4. FIG. 4 is a schematic view illustrating a power transformer in accordance with an embodiment of the present disclosure. As shown in FIG. 4, the power transformer 400 generally includes a primary winding configured to receive power from a power supply; and a secondary winding configured to receive the power from the primary winding and provide the received power to a load, wherein at least one of the primary winding and the secondary winding comprises the coreless planar coil 200 according to embodiments of the present disclosure.

In some embodiments, as shown in FIG. 4, the power transformer 400 comprises four PCBs 401, 402, 403, 404. Each PCB comprises a coreless planar coil 200 according to embodiments of the present disclosure. The primary winding of the power transformer 400 is consisted by the coreless planar coils 200 on the PCBs 402 and 403, and the secondary winding of the power transformer 400 is consisted by the coreless planar coils 200 on the PCBs 401 and 404. With such an arrangement, the coupling coefficient of the primary winding and the secondary winding can be maximized.

In some embodiments, the power transformer 400 may comprise more than four PCBs. The scope of the present disclosure is not intended to be limited in this respect.

In some embodiments, the primary winding and the secondary winding can be arranged in other arrangements. For example, the primary winding can be consisted by the coreless planar coils 200 on the PCBs 401 and 402, and the secondary winding can be consisted by the coreless planar coils 200 on the PCBs 403 and 404. The scope of the present disclosure is not intended to be limited in this respect.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

1. A coreless planar coil, comprising:
a coil body arranged in a plane and configured to produce an alternating magnetic field for delivering signal or power; and
a first metal ring arranged around the coil body in the plane and configured to produce a first magnetic field having a direction opposite to the alternating magnetic field produced by the coil body.

2. The coreless planar coil according to claim 1, wherein the coreless planar coil is arranged on a PCB.

3. The coreless planar coil according to claim 1, further comprising:
a second metal ring arranged inside the coil body in the plane and configured to produce a second magnetic field having a direction opposite to the alternating magnetic field produced by the coil body.

4. The coreless planar coil according to claim 3, wherein the first metal ring and the second metal ring are made of copper.

5. The coreless planar coil according to claim 3, wherein the first metal ring and the second metal ring are made of copper foils on a PCB.

6. A coreless power transformer, comprising:
a primary winding configured to transmit power received from a power supply; and
a secondary winding configured to receive the power from the primary winding and provide the received power to a load,
wherein at least one of the primary winding and the secondary winding comprises the coreless planar coil according to claim 1.

7. The coreless power transformer according to claim 6, wherein the primary winding and the secondary winding are arranged on different PCBs.

8. The coreless power transformer according to claim 6, wherein the coreless planar coil is arranged on a PCB.

9. The coreless power transformer according to claim 6, wherein the coreless planar coil further comprises:
a second metal ring arranged inside the coil body in the plane and configured to produce a second magnetic field having a direction opposite to the alternating magnetic field produced by the coil body.

10. The coreless power transformer according to claim 8, wherein the first metal ring and the second metal ring are made of copper.

11. The coreless power transformer according to claim 8, wherein the first metal ring and the second metal ring are made of copper foils on a PCB.
